(19) United States
(12) Patent Application Publication
(10) Pub. No.: US 2026/0362851 A1
(43) Pub. Date: Nov. 12, 2026

(54) MAGNESIUM ALUMINATE SCANDIUM OXIDE ON VARIOUS SUBSTRATES FOR NITRIDE FILM OVERGROWTH

(71) Applicant: Wisconsin Alumni Research Foundation, Madison, WI (US)

(72) Inventors: Chirag Gupta, Middleton, WI (US); Guangying Wang, Madison, WI (US); Shubhra S. Pasayat, Middleton, WI (US); Shuwen Xie, Madison, WI (US)

(21) Appl. No.: 18/588,920

(22) Filed: Feb. 27, 2024

(51) Int. Cl. H10H 20/01; H10H 20/812; H10H 20/825

(52) U.S. Cl. CPC H10H 20/01335; H10H 20/812; H10H 20/825

(57) ABSTRACT

Heterostructures that include a layer of crystalline ScAlMgO₄ (SAM) on the surface of a substrate are provided. The layer of crystalline SAM is characterized by an ultra-smooth surface and is free of, or substantially free of, the MgAl₂O₄ spinel phase. The high crystal quality, including the smooth surface, of the SAM layer renders the SAM well suited as a growth substrate for group III-nitride-based electronic and optoelectronic devices, including InGaN-based and GaN-based LEDs and LDs.

### REFERENCE TO GOVERNMENT RIGHTS

This invention was made with government support under 1720415 awarded by the National Science Foundation. The government has certain rights to the invention.

### BACKGROUND

Group III-nitrides are useful in a wide range of applications in the fields of electronics and optoelectronics. These include light-emitting devices, such as light-emitting diodes (LEDs) and laser diodes (LDs) that are used in medicine, displays, and even agriculture. Indium-gallium-nitride alloys (InGaN) are particularly useful for longer wavelength (e.g., >530 nm) applications. However, for these long wavelength applications the InGaN needs a high indium (In) concentration.

The use of lattice-matched substrates for the epitaxial growth of InGaN is advantageous because it enables the growth of high-quality crystalline InGaN films that incorporate a high concentration of indium in the InGaN alloy. Zinc oxide (ZnO) is a common and commercially available substrate for the growth of In_{0.22}Ga_{0.78}N, to which it is lattice matched. Unfortunately, because ZnO decomposes at temperatures greater than about 600 °C, the InGaN can only be grown at temperatures below 600 °C, which is sub-optimal. ScAlMgO₄ (SAM) is another useful substrate for epitaxial InGaN growth, since it is lattice-matched with In_{0.17}Ga_{0.83}N and is suitable for high-temperature InGaN growth conditions. However, SAM is expensive and not readily available as large-size substrate.

Attempts have been made to develop SAM-on-sapphire substrates that include a thin film of SAM on an underlying bulk sapphire support for InGaN growth. However, the SAM films grown by the published methods have a significant spinal phase fraction, which results in polycrystallinity and a root-mean-square (RMS) surface roughness (e.g., ≥2 nm) that renders them unsuitable for the growth of very high-quality crystalline InGaN.

### SUMMARY

Heterostructures that include a layer of crystalline SAM on the surface of a c-plane sapphire substrate and light-emitting devices that incorporate the heterostructures are provided.

The heterostructures include: a substrate selected from an Al₂O₃ substrate, a SiC substrate, a AlN substrate, a GaN substrate, a Si (111) substrate, or a diamond substrate; and a layer of crystalline ScAlMgO₄ on a surface of the substrate, wherein the layer of crystalline ScAlMgO₄ has a thickness of at least 5 nm, an RMS surface roughness of 1.0 nm or lower over a surface area of at least 1 μm², and the crystalline ScAlMgO₄ is characterized by an x-ray diffraction pattern in which a MgAl₂O₄ 311 peak and a ScAlMgO₄ 0009 peak have a peak-to-background intensity ratio of no greater than 1:10.

Light-emitting devices that incorporate the heterostructures include: a heterostructure of a type described herein; a plurality of layers of crystalline group III-nitrides on the layer of crystalline ScAlMgO₄, wherein the plurality of layers of crystalline group III-nitrides comprise, from bottom to top or from top to bottom: a layer of n-doped group III-nitride; a group III-nitride-based active region comprising multiple quantum wells; and a layer of p-type doped group III-nitride layer, wherein the active region is disposed between the layer of n-type doped group III-nitride and the layer of p-type doped group III-nitride layer.

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

FIG. 1. Atomic Force Microscopy (AFM) image of SAM-on-c-plane sapphire having a SAM RMS surface roughness of 0.219 nm and corresponding XRD scan.

FIG. 2. AFM image of SAM-on-c-plane sapphire having a SAM RMS surface roughness of 0.287 nm and corresponding XRD scan.

FIG. 3. AFM image of SAM-on-c-plane sapphire having a SAM RMS surface roughness of 0.57 nm and corresponding XRD scan.

FIG. 4. AFM image of SAM-on-c-plane sapphire having a SAM RMS surface roughness of 0.379 nm and corresponding XRD scan.

FIG. 5. AFM images of SAM-on-c-plane sapphire over different surface areas having a SAM RMS surface roughness of 0.205 nm and corresponding XRD scan.

FIG. 6. AFM image of SAM-on-c-plane sapphire having a SAM RMS surface roughness of 0.262 nm and corresponding XRD scan.

FIG. 7. Schematic diagram of an LED on a SAM-on-c-plane sapphire substrate.

FIG. 8. Schematic diagram of an LD on a SAM-on-c-plane sapphire.

FIG. 9. Schematic diagram of an LED on a SAM-on-c-plane sapphire, as described in the Example.

FIG. 10. On-wafer Electroluminescence (EL) measurements, as described in the Example.

FIG. 11. Current density (J)-voltage (V) measurements as described in the Example.

FIG. 12. External quantum efficiency of an InGaN LED grown on SAM on sapphire, sapphire and GaN on sapphire substrate, as described in the Example.

FIG. 13. AFM images of SAM-on-c-plane sapphire, made by sputtering followed by annealing, then sputtering again, having a SAM RMS surface roughness of 0.262 nm and corresponding XRD scan.

### DETAILED DESCRIPTION

Heterostructures that include a layer of crystalline SAM on the surface of a c-plane sapphire ((0001) Al₂O₃) substrate or a substrate with a crystal structure similar to that of c-plane sapphire are provided. The layer of crystalline SAM is characterized by an ultra-smooth surface and is free of, or substantially free of, the MgAl₂O₄ spinel phase. The high crystal quality, including the smooth surface, of the SAM layer renders the SAM well suited as a growth substrate for group III-nitride-based electronic and optoelectronic devices, including LEDs and LDs with InGaN-based and/or GaN-based active device layers (i.e., light-emitting layers).

The SAM is formed as a crystalline layer via radiofrequency (RF) magnetron sputtering followed by a thermal anneal. A detailed description of the methods for forming the SAM layers on c-plane sapphire, or similar substrate, with ultra-smooth surfaces are provided in the Example. To the best of the inventors' knowledge, the fully crystalline SAMs layers have an RMS surface roughness substantially lower than that of any previously reported SAM-on-c-plane sapphire. (See, for example, Wang, Guangying, et al. “MOCVD of InGaN on ScAlMgO₄ on Al₂O₃ Substrates with Improved Surface Morphology and Crystallinity.” Crystals 13.3 (2023): 446; and Chen, Yajin, et al. “Reduction of Interface Reactions in the Low-Temperature Solid-Phase Epitaxy of ScAlMgO₄ on Al₂O₃ (0001).” Crystal Growth & Design 20.9(2020 ): 6001-6007.) Without intending to be bound to any particular theory of the invention, the unprecedented surface smoothness of the crystalline SAM layers may be attributed, at least in part, to the inventors' discovery of the importance of sputtering chamber pressure in achieving high-quality SAM, as reflected in the Example below.

The crystalline SAM layers are single-crystalline and phase-pure or substantially phase-pure. Thus, the crystalline SAM layers are free of, or substantially free of, non-ScAlMgO₄ material phases. As it is the spinel phase (MgAl₂O₃) that, if present, will be the most common secondary phase, the phase-purity of the SAM can be determined by the peak-to-background intensity ratios for the spinel 311 peak and the ScAlMgO₄ 0009 peak in the x-ray diffraction (XRD) pattern for the SAM layer. Using the methods described in the Example, SAM layers having a spinel 311 peak and a ScAlMgO₄ 0009 peak with a peak-to-background intensity ratio of no greater than 1:10 can be formed on c-plane sapphire. This includes SAM layers having a spinel 311 peak and a ScAlMgO₄ 0009 peak with a peak-to-background intensity ratio of no greater than 1:20.

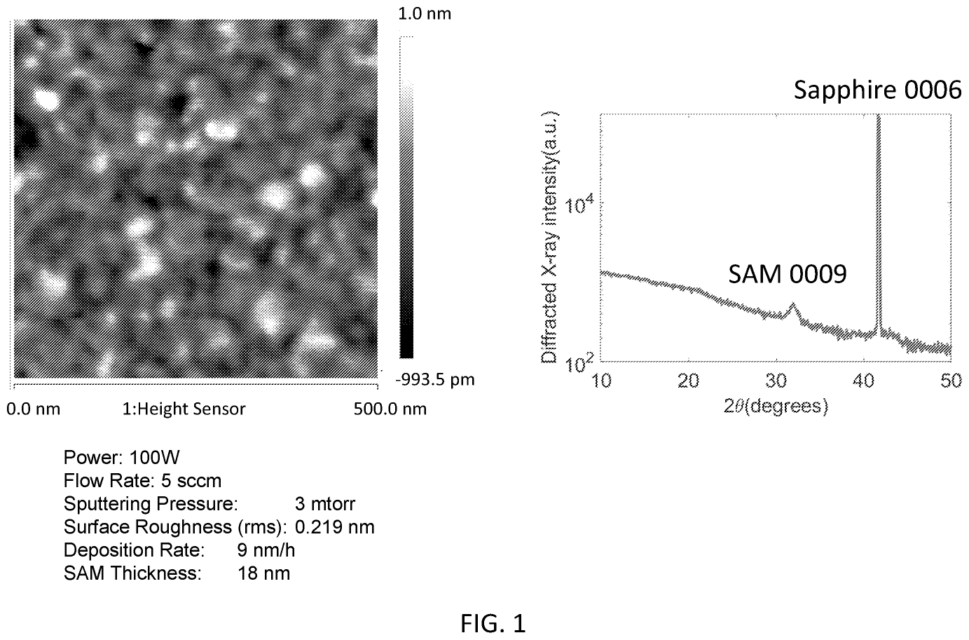

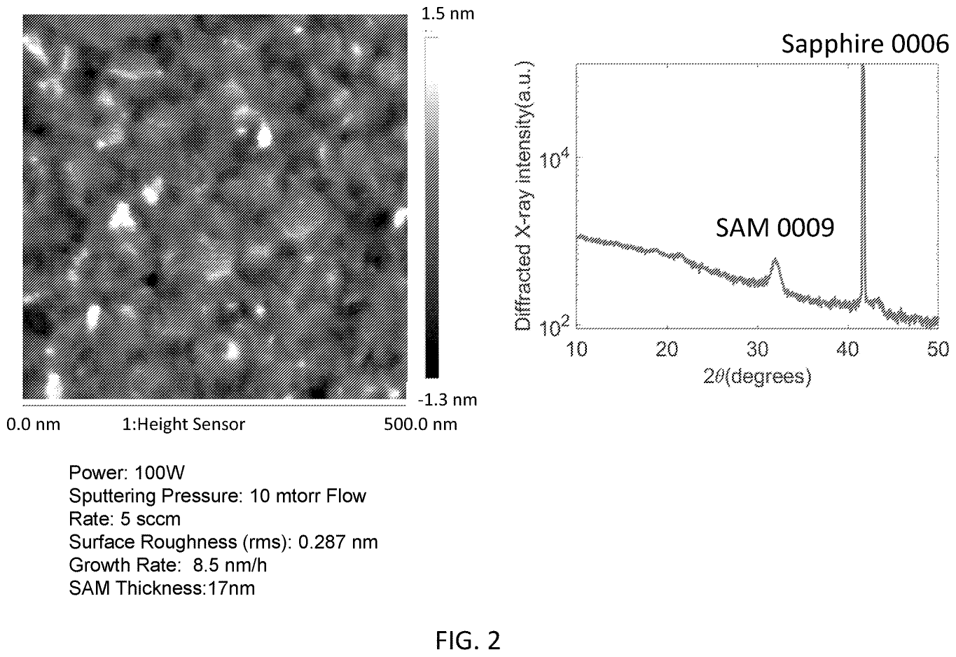

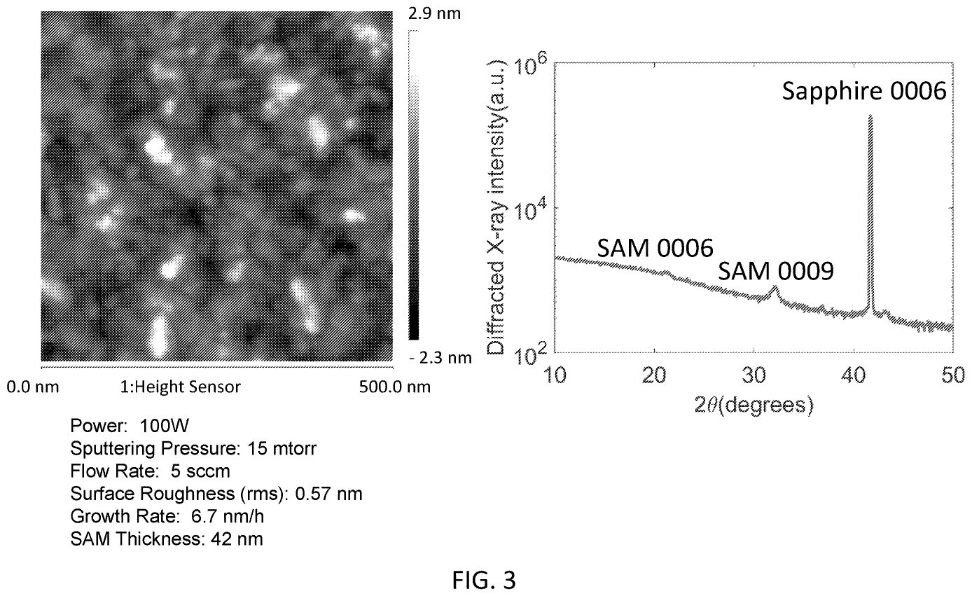

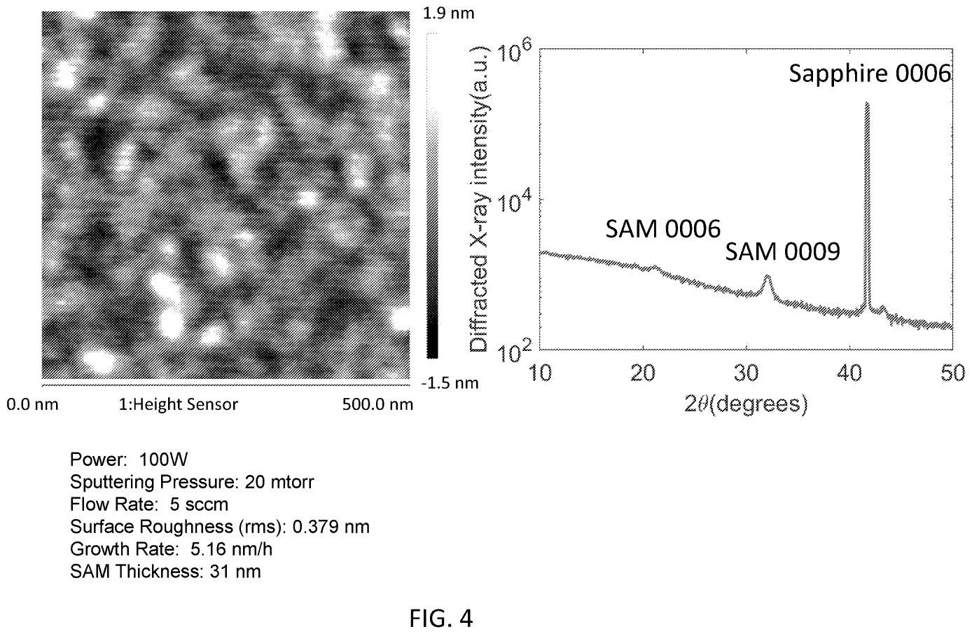

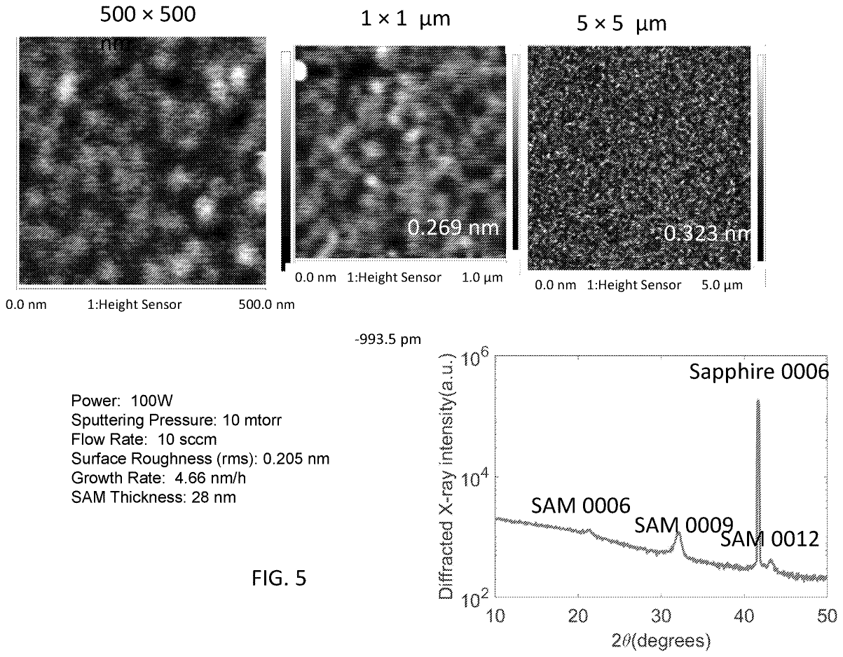

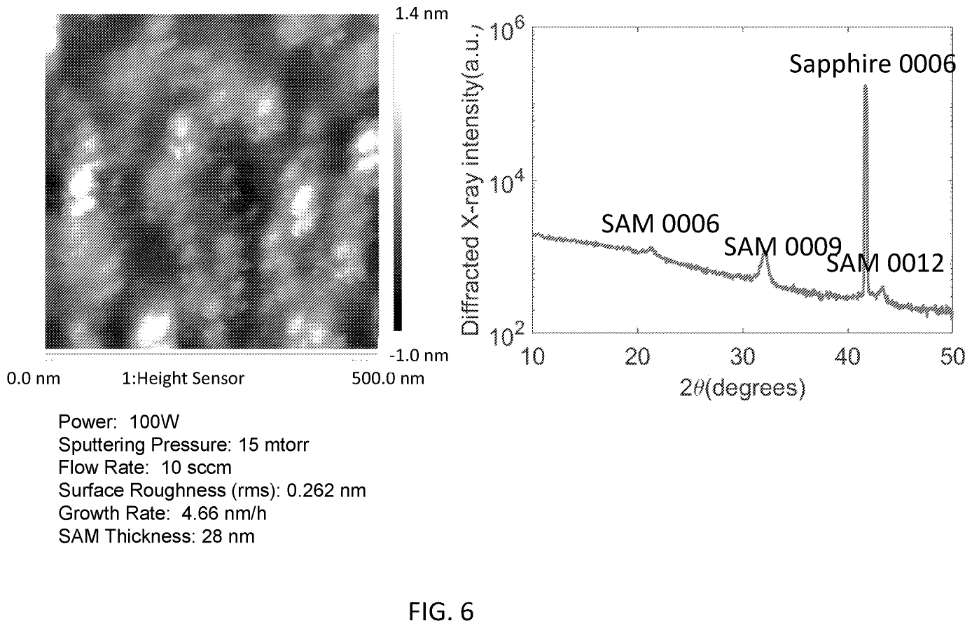

The phase-purity of the SAM layers is reflected in the low roughness of their surfaces. The surface roughness of the SAM layers on the c-plane sapphire can be measured as the RMS Ra parameter from AFM images. FIGS. 1-6 show four AFM images of SAM-on-c-plane sapphire. Based on the AFM images, each of the SAM layers had an RMS surface roughness of less than 1.0 nm. In fact, the SAM surfaces in these images include those having an RMS surface roughness of less than 0.60 nm, less than 0.50 nm, less than 0.40 nm, less than 0.30 nm, and less than 0.20 nm, demonstrating that the methods described in the Example can be used to form SAM-on-c-plane sapphire with an RMS SAM surface roughness in the range from about 0.10 nm to 1.0 nm, including in the range from about 0.20 nm to about 0.60 nm.

The high-phase-purity, low-surface-roughness SAM layers can be achieved even for relatively thick SAM layers. This is notable since previous attempts to grow smooth SAM-on-sapphire have observed a degradation in surface roughness with increasing thickness. By way of illustration, the fully crystalline SAM layers formed on-c-plane sapphire (or on a substrate having a similar crystal structure) described herein can have the above-described high phase-purities and low surface roughnesses even at thicknesses of at least 5 nm, at least 20 nm, at least 30 nm, at least 40 nm, and at least 50 nm, including, for example, at thicknesses in the range from 30 nm to 100 nm.

While the SAM layers in the Example are grown on c-plane sapphire, the methods described therein can be used to form SAM layers having the low RMS surface roughness properties and phase-purities at the same layer thicknesses on other substrates having crystal structures that are sufficiently similar to the crystal structure of c-plane sapphire. These substrates include sapphire substrates with other orientations, such as m-plane and a-plane, SiC substrates, AlN substrates, bulk GaN substrates, Si (111) substrates, and diamond substrates. The sapphire substrates can miscut. For illustrative purposes only, miscuts in the range of 2 to 5 degrees may be used.

### Light-Emitting Devices

The SAM-on-sapphire substrates described herein can be used as substrates for the epitaxial growth of group III-nitride heterostructures. Such devices include light-emitting devices, such as LEDs and LDs. Some embodiments of the LEDs and LDs emit at wavelengths from the deep ultraviolet (UV) through the near infrared (near IR), including green-emitting LEDs and yellow-emitting LDs.

In the light-emitting devices, carriers (electrons and holes) are injected into an active region comprising multiple quantum wells (MQWs) under the influence of an electric field applied across the device heterostructure. In the active region, the carriers recombine to emit photons. In addition to the active region, the devices include two or more electrically conductive contacts positioned to apply the electric field across the heterostructure, including across the MQWs in the active region, and a voltage source coupled to the electrically conductive contacts to apply a voltage difference between the contacts, thereby generating the electric field. Electrically conductive contacts that are positioned to apply an electric field across the active region when the light-emitting device is in operation are referred to as being in electrical communication with the active region. However, the electrically conductive contacts need not be in direct physical contact with the active region; they may be separated from the active region by one or more additional device layers.

### LEDs

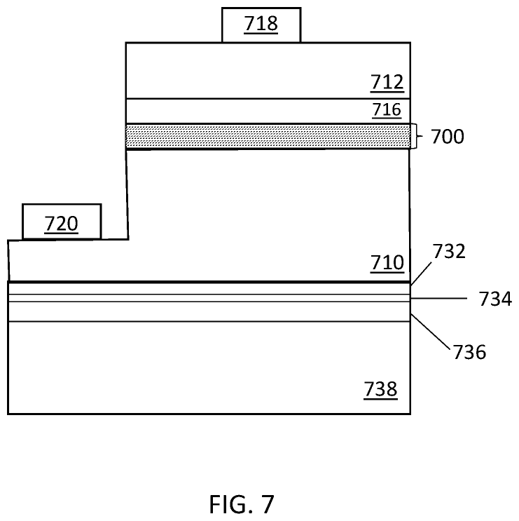

FIG. 7 is a schematic diagram of a heterostructure for an LED grown on ultra-smooth SAM on a substrate, such as c-plane sapphire. In the LED, an active region having an MQW structure 700 is disposed between an electron-injection layer 710 comprising an n-type semiconductor and a hole-injection layer 712 comprising a p-type doped semiconductor. Optionally, an electron-blocking layer (EBL) 716 comprising a p-type semiconductor having a higher bandgap than the p-type doped semiconductor of hole-injection layer 712 may be disposed between hole-injection layer 712 and active region 700 to avoid leakage of electrons into the p-type doped semiconductor. Electron-injection layer 710, hole-injection layer 712, and EBL 716 may be made from various group III-nitride semiconductors.

In some embodiments of the LEDs, the electron-injection layer 710 is provided by a strain-relaxed, n-type doped InGaN buffer layer 710, on a GaN cap layer 532, on an InGaN nucleation layer 734 on a growth substrate comprising ultra-smooth SAM (736)-on-substrate, wherein the substrate 738 may be bulk c-plane sapphire or a similar substrate, as described herein.

During operation of the LED, a forward bias is applied using an electrically conducting (typically metallic) p-contact 718 on hole-injection layer 712 and an electrically conducting (typically metallic) n-contact 720 on electron-injection layer 710. This applied bias causes electrons from the electron-injection layer and holes from the hole-injection layer to flow to the active region 700, where they are captured by quantum wells and recombine to generate light. Suitable p-type doped semiconductors for the hole-injection and electron-blocking layers include, but are not limited to, Mg-doped InGaN; suitable n-type doped semiconductors for the electron-injection layer include Si-doped InGaN or Si-doped AlInGaN, and suitable semiconductors for the MQW structure include InGaN/AlGaN/GaN.

### LDs

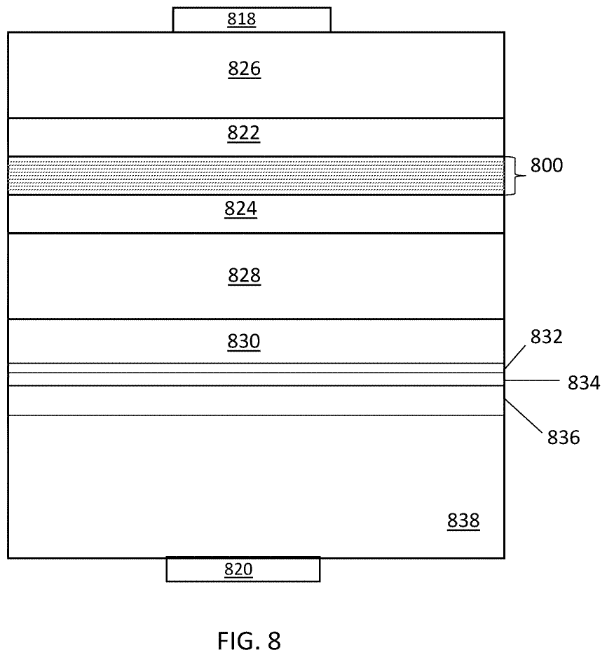

FIG. 8 is a schematic diagram of an LD. In the LD, the active region 800 is disposed between a first waveguide layer 822 comprising a p-type doped or undoped group III-nitride semiconductor and a second waveguide layer 824 that is disposed opposite first waveguide layer 822 and comprises an undoped or n-type doped group III-nitride semiconductor. A first cladding layer 826 comprising a p-type doped group III-nitride semiconductor is disposed over first waveguide layer 822 and a second cladding layer 828 comprising an n-type doped group III-nitride semiconductor is disposed below second waveguide layer 824 and opposite first cladding layer 826. Optionally, an EBL comprising a p-type doped group III-nitride semiconductor can be inserted between first waveguide layer 822 and first cladding layer 826 or between the MQW active region 800 and first waveguide layer 822. The waveguide layers are characterized in that they are more lightly-doped than their respective cladding layers.

Second cladding layer 828 is grown on a group III-nitride heterostructure that includes a strain-relaxed, n-type doped InGaN buffer layer 830, GaN cap layer 832, and InGaN nucleation layer 834 on a growth substrate comprising ultra-smooth SAM (836)-on-substrate 838 (e.g., SAM-on-sapphire or another similar substrate). Optionally, an electron-blocking layer (EBL) (not shown) comprising a p-type semiconductor having a higher bandgap than the first waveguide layer 822 may be disposed between first waveguide layer 822 and active region 810.

Suitable materials for the various layers of the LD shown in FIG. 8 include, but are not limited to: waveguide layers (822, 824)—InGaN or GaN; p-cladding (826)—InGaN (with a lower In content than the waveguide), preferably GaN, AlGaN, AlInGaN; n-cladding (628)—InGaN (with lower In content than the waveguide), preferably GaN, AlGaN, AlInGaN, and closely lattice matched to the InGaN layer (830); and active region (600)—InGaN/AlGaN/GaN.

### Device Fabrication

The group III-nitride layers in the heterostructures and light-emitting devices, including the active region, can be grown using vapor deposition methods, such as MOCVD, plasma chemical vapor deposition (CVD), or hot-filament CVD, or by molecular beam epitaxy (MBE). The metal contacts can be deposited by metal deposition techniques, such as atomic layer deposition (ALD), sputtering, or evaporation. Various metals, metal alloys, and electrically conducting oxides can be used to form electrically conducting contacts. By way of illustration only, contacts can be composed of gold, platinum, chromium, tungsten, titanium, aluminum, nickel, gold, or alloys thereof.

If the growth of the heterostructure utilizes MBE, growth may take place in a vacuum chamber in which a growth substrate typically is supported on a rotatable platform. A heat source (e.g., a resistive heater) in thermal communication with the growing heterostructure can be used to tailor the growth temperature for each of the various material layers to provide high-quality crystal growth.

Epitaxial growth using vapor deposition is carried out by exposing the substrate or the previously grown layer of the heterostructure to metal-containing and nitrogen-containing precursor molecules that decompose and react to form the various layers. These precursors may be introduced into the vacuum chamber with a carrier gas, such as hydrogen (H₂) or nitrogen (N₂). For MOCVD growth, the precursors are metal-organic compounds, such as trimethyl gallium (TMGa), triethyl gallium (TEGa), trimethyl aluminum (TMAl), triethyl aluminum (TEAl), trimethyl indium (TMI), and triethyl indium (TEI). Ammonia (NH₃) is typically used as a nitrogen precursor molecule. For the growth of doped semiconductors, a dopant-containing precursor (e.g., silane (SiH₄) for Si doping or magnesocene (bis (cyclopentadienyl) magnesium (Cp₂Mg)) for Mg doping) is also introduced into the chamber.

By adjusting the carrier gases, precursor gas flow rates, pressures, growth temperature, or a combination thereof during the growth of a material layer, high quality crystal layers with precisely tailored material properties can be grown.

### EXAMPLE

This example described the MOCVD growth of SAM-on-sapphire substrates in which the SAM layer has an RMS surface roughness of less than 0.5 nm over a surface area of 1 μm² or greater. A two-step solid phase epitaxy was performed to create crystalline SAM on sapphire wafers: (1) SAM deposition via magnetron RF sputtering and (2) SAM crystallization via annealing.

### Sapphire Wafer Preparation

Before SAM deposition, 2″ sapphire wafers were annealed at high temperatures for various durations. The pre-annealing step improved the surface morphology, and the oxygen-terminated surface aided the formation of the crystalline film above the sapphire substrate. The duration of this step was from 3 hours to 10 hours, with a temperature range from 950 °C to 1400 °C. Rapid thermal annealing could also be used for this step.

### Radiofrequency Magnetron Sputtering

SAM amorphous films were deposited on the pre-annealed 2″ sapphire wafers. Commercial and home-made sputtering targets were used to deposit SAM films on the sapphire wafer substrates. The commercially available RF sputtering target used to deposit the amorphous SAM on a sapphire substrate was a 99.99% purity 3″ SAM sputtering target with a thickness of 0.125″ purchased from Advanced Engineering Materials. It was bonded to a 3″ Cu backing plate of thickness of 0.125″ with elastomer. The target was manufactured using cold press technology with Sc₂O₃:MgO:Al₂O₃=1:2:1.

The home-made sputtering target was a: 99.9% purity SAM target with a 2″ diameter bonded to a raised AJA international PowerRing backing plate having a 0.125″ thickness. The target was manufactured to a composition of Sc₁₂—Al—Mg—O₄.

The following conditions were used for sputtering: chamber pressures in the range from 3 mTorr to 20 mTorr; Ar flow rates in the range from 5 sccm to 10 sccm, and a sputtering power of 100 W. Specific sputtering conditions used to deposit the SAM layers on the c-plane sapphire are provided in FIGS. 1-6. Crystalline SAM films with thicknesses in the range from 17 nm to 46 nm and RMS surface roughnesses in the range from 0.205 to 0.57 nm were produced.

### SAM Crystallization via Thermal Anneal

The amorphous SAM films deposited on the sapphire wafers were annealed at temperatures in the range from 775 to 1000 °C (e.g., 950 °C) for periods of 10 to 25 hours to fully convert the amorphous SAM films into crystalline SAM films. The films were annealed for longer times and their crystallinity did not change, indicating that the films were fully crystalized.

### Crystalline SAM Characterization

The surface roughness of the crystallized SAM films was measured using Atomic AFM scans using a Bruker Icon AFM tool. The roughnesses of the films were evaluated through the root-mean-square (RMS) Ra parameter. The thickness of the SAM layer was measured with X-ray reflectivity (XRR) using the Panalytical Empyrean X-ray diffractometer. SAM-phase and spinel-phase MgAl₂O₄ peaks were identified with the indexes from previously reported structures. The quality of the crystallized SAM layer was evaluated by comparing the spinel (311) to SAM (0009) peak-to-background intensity ratio, the SAM (0009) peak's full width of half maximum range (FWHM), and the spinel (311) peak's FWHM from the (omega)-2theta scans.

### Results

AFM images for four fully crystallized SAM films on sapphire having RMS surface roughnesses of less than 1 nm are shown if FIG. 1-6. Below each AFM image, the power, Ar flow rate, sputtering pressure, and deposition rate used during sputtering is provided, along with the RMS surface roughness and thickness of the resulting SAM layer.

The XRD patterns corresponding to the AFM images in FIGS. 1-6 are shown to the right of the images. The peak-to-background intensity ratios for the spinel 311 peak and the ScAlMgO₄ 0009 peak are reported below each figure, and in each instance is less than 1:10.

### Light-Emitting LED on SAM-on-Sapphire

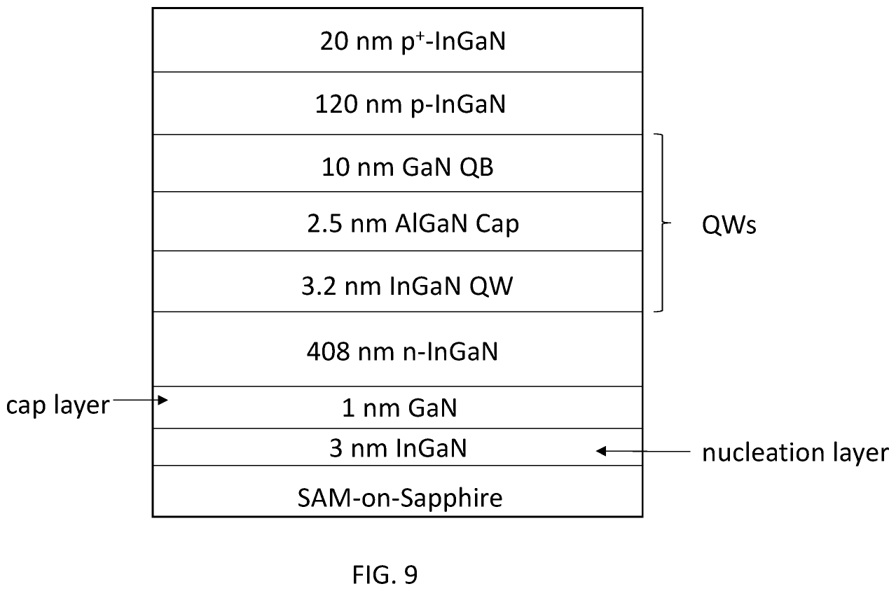

To demonstrate the utility of the SAM-on-sapphire substrates as growth substrates for the epitaxial growth of InGaN alloys-based LEDs, an LED was grown on the SAM-on-sapphire substrate having a SAM surface roughness of 0.57 nm. The LED heterostructure, including the layer thicknesses and materials are shown schematically in FIG. 9.

In the LED, a nucleation layer of In_{0.15}Ga_{0.85}N was grown to a thickness of 3 nm followed by the growth of a GaN cap layer with a thickness of 1 nm. N-doped InGaN (n-In_{0.15}Ga_{0.85}N; Si-doped) was grown to a thickness of 408 nm on the GaN cap layer. Next an active region comprising three InGaN/AlGaN/GaN QWs was grown via MOCVD to target thicknesses of 3.2 nm/2.5 nm/10 nm, respectively. The AlGaN had an Al content of 10%, as measured by RSM. A 120 nm-thick layer of p-InGaN (Mg-doped InGaN) was grown on the active region, followed by the growth of a 20 nm-thick, heavily doped p-InGaN layer to form contacts for the LED. Bis(cyclopentadienyl) magnesium (Cp₂Mg) was used as the Mg precursor for p-doping the InGaN. The MOCVD growth conditions for the LED device layers were the same as those used in Shubhra S. Pasayat et al 2021 Appl. Phys. Express 14 011004.

The LED successfully emitted blue electroluminescence with a peak emission wavelength of 515 nm at a current density of 1 A/cm².

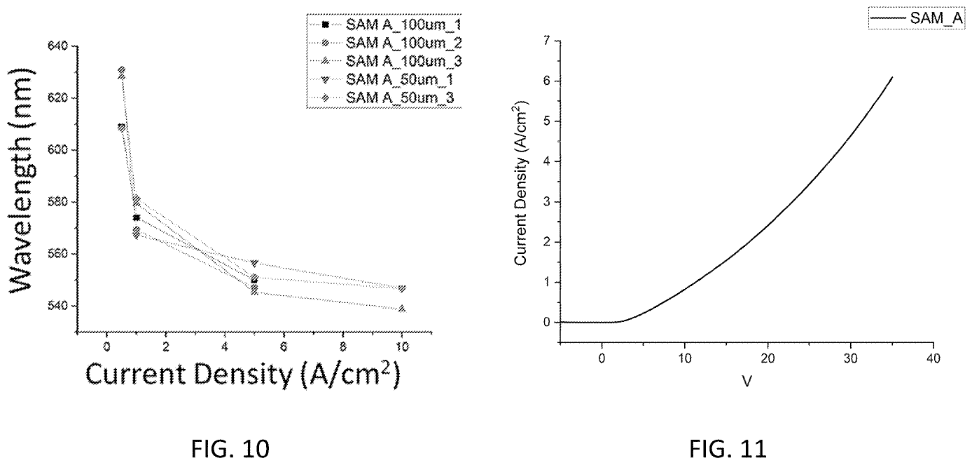

Additional data is provided in FIGS. 10-12. FIG. 10 shows the on-wafer electroluminescence (EL) measurements conducted on the backside of the sample (through the sapphire substrate). While LED devices were probed on the top surface, the light from the quantum wells was transmitted through the sapphire substrate using a cosine corrector (Ocean Insight CC-3-UV-S) positioned on the backside. Subsequently, this light was carefully guided through an optical fiber and a pair of Plano-Convex lenses before it entered the Horiba iHR320 spectrometer. EL spectra were obtained through the combined use of the iHR320 spectrometer and a thermoelectrically cooled CCD detector (Horiba Synapse CCD). To ensure the utmost precision, this optical system was meticulously calibrated, a procedure involving a radiometric calibrated light source (Ocean Insight DH-3P-CAL).

FIG. 11 shows current density (J)-voltage (V) measurements performed using Keysight B1505.

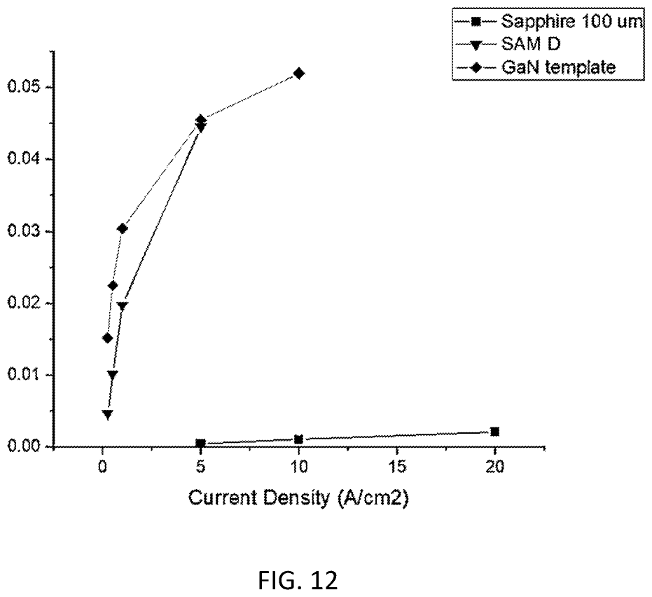

FIG. 12 shows external quantum efficiency of InGaN LEDs grown on SAM on sapphire, sapphire and GaN on sapphire substrates.

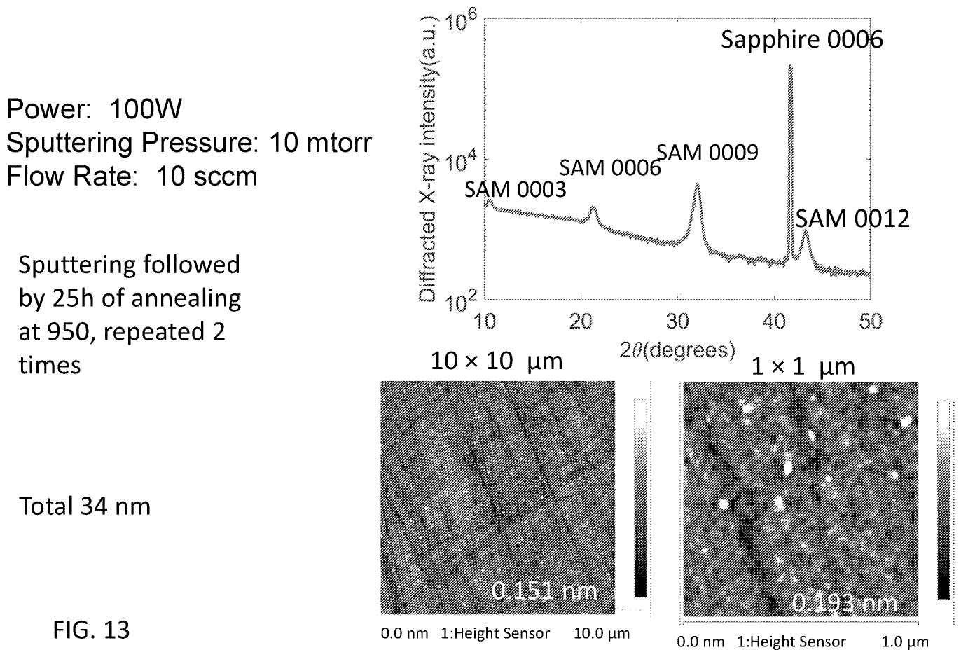

FIG. 13 shows AFM images of SAM-on-c-plane sapphire, made by sputtering followed by annealing, then sputtering again, having a SAM RMS surface roughness of 0.262 nm. The corresponding XRD scan is also shown in the figure.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A heterostructure comprising:
a substrate selected from an Al₂O₃ substrate, a SiC substrate, a AlN substrate, a GaN substrate, a Si (111) substrate, or a diamond substrate; and
a layer of crystalline ScAlMgO₄ on a surface of the substrate, wherein the layer of crystalline ScAlMgO₄ has a thickness of at least 5 nm, an RMS surface roughness of 1.0 nm or lower over a surface area of at least 1 μm², and the crystalline ScAlMgO₄ is characterized by an x-ray diffraction pattern in which a MgAl₂O₄ 311 peak and a ScAlMgO₄ 0009 peak have a peak-to-background intensity ratio of no greater than 1:10.

2. The heterostructure of claim 1, wherein the RMS surface roughness of the layer of crystalline ScAlMgO₄ is no greater than 0.50 nm.

3. The heterostructure of claim 1, wherein the RMS surface roughness of the layer of crystalline ScAlMgO₄ is no greater than 0.30 nm.

4. The heterostructure of claim 1, wherein the thickness of the layer of crystalline ScAlMgO₄ is at least 20 nm.

5. The heterostructure of claim 1, wherein the thickness of the layer of crystalline ScAlMgO₄ is at least 30 nm.

6. The heterostructure of claim 2, wherein the RMS surface roughness of the layer of crystalline ScAlMgO₄ is in the range from 0.20 to 0.50.

7. The heterostructure of claim 2, wherein the thickness of the layer of crystalline ScAlMgO₄ is in the range from 30 nm to 100 nm.

8. The heterostructure of claim 6, wherein the thickness of the layer of crystalline ScAlMgO₄ is in the range from 30 nm to 100 nm.

9. The heterostructure of claim 1, further comprising one or more layers of crystalline group III-nitride on the surface of the layer of crystalline ScAlMgO₄.

10. The heterostructure of claim 9, wherein the one or more layers of crystalline group III-nitride comprise a layer of crystalline InGaN alloy.

11. The heterostructure of claim 1, wherein the substrate is the c-plane Al₂O₃ substrate.

12. The heterostructure of claim 11, wherein the RMS surface roughness of the layer of crystalline ScAlMgO₄ is no greater than 0.50 nm.

13. The heterostructure of claim 11, wherein the RMS surface roughness of the layer of crystalline ScAlMgO₄ is no greater than 0.30 nm.

14. The heterostructure of claim 11, wherein the thickness of the layer of crystalline ScAlMgO₄ is at least 20 nm.

15. The heterostructure of claim 11, wherein the thickness of the layer of crystalline ScAlMgO₄ is in the range from 0.20 to 0.50 and the thickness of the layer of crystalline ScAlMgO₄ is in the range from 30 nm to 100 nm.

16. A light-emitting device comprising:
a heterostructure comprising:
a substrate selected from an Al₂O₃ substrate, a SiC substrate, a AlN substrate, a GaN substrate, a Si (111) substrate, or a diamond substrate; and
a layer of crystalline ScAlMgO₄ on a surface of the substrate, wherein the layer of crystalline ScAlMgO₄ has a thickness of at least 5 nm, an RMS surface roughness of 1.0 nm or lower over a surface area of at least 1 μm², and the crystalline ScAlMgO₄ is characterized by an x-ray diffraction pattern in which a MgAl₂O₄ 311 peak and a ScAlMgO₄ 0009 peak have a peak-to-background intensity ratio of no greater than 1:10; and
a plurality of layers of crystalline group III-nitrides on the layer of crystalline ScAlMgO₄, wherein the plurality of layers of crystalline group III-nitrides comprise, from bottom to top or from top to bottom:
a layer of n-doped group III-nitride;
a group III-nitride-based active region comprising multiple quantum wells; and
a layer of p-type doped group III-nitride layer, wherein the active region is disposed between the layer of n-type doped group III-nitride and the layer of p-type doped group III-nitride layer.

17. The light-emitting device of claim 16, wherein the n-doped group III-nitride is InGaN or GaN and the light-emitting device is a light-emitting diode.

18. The light-emitting device of claim 16, wherein the n-doped group III-nitride is InGaN or GaN and the light-emitting device is a diode laser.

19. The light-emitting device of claim 16, wherein the device emits light in a range from 3.4 eV to 0.7 eV.

20. The light-emitting device of claim 16, wherein the substrate is the c-plane Al₂O₃.
